(19) United States
(12) Patent Application Publication
(10) Pub. No.: US 2023/0142960 A1
(43) Pub. Date: May 11, 2023

(54) CONSTRUCTION OF FORMWORK AND SCAFFOLDING USING MOBILE DEVICES

(71) Applicant: PERI GMBH, Weißenhorn (DE)

(72) Inventors: Sven Michael Peper, Weissenhorn (DE); Miguel Angel Lopez Buitrago, Weissenhorn (DE); Pablo Lopez Buitrago, Weissenhorn (DE)

(21) Appl. No.: 17/459,381

(22) PCT Filed: Feb. 25, 2020
(86) PCT No.: PCT/EP2020/054872

§ 371 Date: Aug. 27, 2021

(30) Foreign Application Priority Data
Feb. 27, 2019 (DE) 10 2019 105 015.4

(51) Int. Cl. G06F 30/13; G06T 7/80; G06T 7/00

(52) U.S. Cl. CPC G06F 30/13; G06T 7/80; G06T 7/0002; G06T 2207/30204; G06T 2207/10028

(57) ABSTRACT

Method (100) for calibrating an internal coordinate system (11) of a mobile device (1) against an absolute coordinate system (21) of a construction site (2), comprising the steps:
Images and/or scans (3a-3c) showing at least part of the construction site (2) are taken (110), and/or positions (4a-4c) of the mobile device (1) in a fixed coordinate system (4) are determined (120) using a terrestrial or satellite positioning system;
the position (12a-12c) and/or orientation (13a-13c) of the mobile device (1) in the internal coordinate system (11) of the mobile device (1) is additionally sensed (111, 121);
equations (51-56) are established (130) with unknowns (5a-5c) characterizing the sought transformation between the internal coordinate system (11) of the mobile unit (1) and the absolute coordinate system (21) of the site (2) by recognizing (131) geometric features (22), and/or by comparing (132) positional determinations;
the unknowns (5a-5c) are determined as solutions of a system of equations (5) formed from the equations (51-56) set up (140).

Method (200) for quality control of a formwork and/or a scaffold.

### REFERENCE TO RELATED APPLICATIONS

This application claims priority to German Patent Application No. 10 2019 105 015.4, filed Feb. 27, 2019, which is incorporated herein by reference in its entirety.

The invention relates to computer-implemented assistance in the erection and control of formwork and scaffolding on construction sites.

### STATE OF THE ART

When a structure is constructed by pouring concrete, a formwork is usually used as a casting mould for the fresh concrete. In order to be able to produce a formwork quickly and to be able to reuse the material many times, formwork systems comprising prefabricated standard elements are used. An exemplary such formwork system is known from WO 2005/040 525 A1. Similarly, scaffolds are also constructed from prefabricated standard elements.

With the increasing professionalization of the formwork and scaffolding market, the complexity of formwork and scaffolding has also continued to grow. In many cases, solutions trimmed for efficiency and pre-planned in CAD programs are used. For such a solution to achieve the desired technical effect in terms of material consumption, stability or other criteria taken into account during planning, it is essential that the planning is followed precisely during physical erection on the construction site. The personnel on the construction site are often not aware of this, so that in practice there are deviations from the planning, which is thus taken ad absurdum. Support during assembly by representatives of the construction suppliers who have the necessary knowledge can avoid such errors, but is comparatively expensive.

### OBJECT AND SOLUTION

It is therefore the object of the invention to make mobile devices usable for computer assistance in the erection of formwork and/or scaffolding on construction sites.

This object is solved according to the invention by a method for calibration according to the main claim and by a method for computer-assisted quality control according to the subsidiary claim. Further advantageous embodiments result from the subclaims referring back thereto.

### DISCLOSURE OF THE INVENTION

In the context of the invention, a method for calibrating an internal coordinate system of a mobile device against an absolute coordinate system of a site has been developed. In particular, this absolute coordinate system can be a world coordinate system which assigns a latitude and longitude on the earth's surface to each location. However, it can also be spanned starting from any other fixed point and use other coordinates. For example, the curvature of the earth is not relevant for most construction projects, so that Cartesian coordinates can be used.

In the method, at a plurality of positions on the construction site, and/or with a plurality of orientations of the mobile device, at least one image and/or scan showing at least part of the construction site is taken with the mobile device in each case, and/or a terrestrial or satellite positioning system is used to determine the position of the mobile device in a coordinate system which is in a known fixed relation to the absolute coordinate system of the construction site.

For example, the image may be captured by one or more cameras of the mobile device. For example, a single camera may be used to capture a two-dimensional image. A three-dimensional image may be captured using a combination of a camera and a depth sensor, or for example a stereoscopic array of two or more cameras. A scanner, for example emitting a laser beam, can be used to take a scan indicating, for example, starting from the location of the mobile device, for each spatial direction, the distance to the point where the laser beam is reflected.

For example, a satellite-based positioning system may provide a position of the mobile device in world coordinates comprising fractions of latitude and longitude. For example, the absolute coordinate system of the site may be a Cartesian coordinate system, wherein the world coordinates of at least one fixed point of that coordinate system are known.

During each recording and/or position determination, the position and/or orientation of the mobile device in the internal coordinate system of the mobile device is additionally detected by sensors. For example, acceleration sensors, inertial sensors, tilt sensors, angular rate sensors and/or gyroscopes may be used for this purpose. For example, linear accelerations and/or angular accelerations can be double-integrated to update the position of the mobile device starting from a last known position.

Equations are set up with unknowns that characterize the sought transformation between the internal coordinate system of the mobile device and the absolute coordinate system of the construction site. The unknowns are determined as solutions of a system of equations formed from the set up equations, so that the sought transformation is obtained.

The equations can be obtained in two different ways.

On the one hand, at least one geometric feature with a known position in the absolute coordinate system of the construction site can be detected in an image and/or scan, and/or in a three-dimensional actual model of the construction site determined from a plurality of images and/or scans. In conjunction with the position and orientation of the mobile device in the internal coordinate system of the mobile device detected by sensors, this results in an equation whose solutions characterize those transformations between the internal coordinate system of the mobile device and the absolute coordinate system of the construction site at which
the position and orientation of the mobile device in its internal coordinate system as detected by sensors,
the shape, orientation and position of the geometric feature in the image and/or scan, and
the known position of the geometric feature in the absolute coordinate system of the construction site
   are consistent with each other as far as possible without contradiction. For example, the shape, orientation and position of the geometric feature in the image and/or scan can be predicted from the known position of the geometric feature in the absolute coordinate system in conjunction with the transformation of this position into the internal coordinate system of the mobile device and the position of the mobile device in this internal coordinate system. If the transformation is correct, then the geometric feature should appear in the image and/or scan exactly as predicted.

On the other hand, the position determined with the positioning system can be related to the position determined by sensors in the internal coordinate system of the mobile device. In this case, an equation is obtained whose solutions represent those transformations with which coordinates of the position determined with the positioning system in the absolute coordinate system of the construction site can be mapped as free of contradictions as possible to the position determined by sensors in the internal coordinate system of the mobile device.

Each of these equations usually has several solutions, so that several equations are necessary to uniquely determine the transformation sought. Conversely, a solution to a system of equations consisting of several equations will usually not be able to satisfy all equations exactly, but will satisfy each equation only to a certain error, in which case, for example, the mean square error over all equations can be minimized. The reason for this is that the physical measurements included in the equations are subject to unavoidable uncertainties.

In particular, equations based on the recognition of geometric features in images and/or scans and equations based on the direct comparison of coordinates determined in different ways may be combined in the system of equations in any way.

It was realized that by solving the described system of equations, it is possible to determine a transformation between the internal coordinate system of the mobile device and the absolute coordinate system of the construction site that approximates reality to an accuracy of a few millimeters or better. The key to this is the great flexibility in the type and number of information brought together in the form of equations.

Typically, different conditions prevail on different construction sites as far as the availability of information is concerned. For example, at an outdoor construction site, there may be an unobstructed view of the satellites of a navigation system, which allows the localization of individual points in world coordinates with an accuracy down to a few centimeters. On a construction site in a covered hall, on the other hand, satellite-based navigation may be limited or unavailable, while at the same time the lack of weather influences allows better recognition of geometric features in images and/or scans. With the system of equations, the amount of information that is physically available can always be taken as given and optimally evaluated with respect to the sought transformation.

The precise transformation between the coordinate systems obtained in this way is in turn the door opener for computer support in the physical realization of a formwork and/or scaffold. As previously explained, complex formwork and scaffolding are planned in advance using CAD programs. This means that a three-dimensional model of the formwork, or scaffolding, is available in the absolute coordinate system of the construction site. In contrast, images or scans taken by the mobile device to facilitate or check the physical realization of the formwork, or scaffolding, are available in the internal coordinate system of the mobile device. Thus, the image, and/or the scan, in the absolute coordinate system of the construction site, and/or the three-dimensional model in the internal coordinate system of the mobile device, are required. This is exactly what the transformation determined with the described method does.

For example, the three-dimensional model of the formwork or scaffolding can then be superimposed as “augmented reality” on a current view of the construction site from the perspective of the mobile device, so that this view is supplemented by the formwork or scaffolding to be erected.

For example, on a smartphone or tablet PC as a mobile device, a perspective-correct two-dimensional projection of the three-dimensional model can be superimposed on a two-dimensional image currently recorded by a camera of the mobile device and shown on a display. Advantageously, the opacity of this projection can be selected in such a way that the user can visually recognize to what extent the physical structure of the formwork, or of the scaffolding, is congruent with the target model. The same is also possible with virtual reality or mixed reality glasses as a mobile device, whereby this offers the further advantage that the user, using both hands, can position each individual part exactly in its intended place according to the target model.

For example, such goggles may capture images of the construction site via one or more cameras pointed at the construction site, and these images may be transmitted to a display inside the goggles. When shown on the display, the images may be overlaid with the two-dimensional projection of the three-dimensional model. In doing so, the images of the construction site can also be processed, for example, with a wide-angle effect, so that the display on the display covers a larger field of view than is normally detectable by the human eye.

Augmented reality glasses can also be used, for example, which allow a direct optical view through to the physical scenery instead of recording this scenery with a camera and showing the image on a display. The projection of the three-dimensional model can then be partially superimposed on the direct optical view-through, for example.

Due to the direct visual comparison of the physical scenery on the construction site, deviations from the plan and errors in the assembly of the formwork or scaffolding are directly recognizable and can be corrected in time. This is particularly advantageous when a building or part of a building is not constructed “in one pour”, but in several working cycles: The accuracy with which the individual working cycles seamlessly follow each other is then advantageously improved.

Detectable errors can include, in particular, errors that endanger the stability of the formwork or scaffolding, such as forgotten, interchanged or incorrectly (e.g. upside down) mounted fasteners. Not all of these errors can already be prevented during the design of the standard elements, for example by only snapping together parts that match each other in the correct orientation.

The erection of the scaffolding, or the formwork, supported by “augmented reality” can generally improve the accuracy in the final construction of the building or part of the building, beyond the mere avoidance of deviations from the plan and errors. The transformation between the coordinate systems may be supported by a great many equations, so that individual measurement errors in the acquisition of images and/or scans, in the sensor-based position determination and/or in the position determination with the positioning system are lost in the mass of information. If, on the other hand, a formwork or scaffolding is planned conventionally, the superstructure plan is often only drawn on the basis of a few measurements in the physical world. Small inaccuracies in these measurements or in the manual marking out then have an unhindered effect on the final result.

Alternatively or also in combination with the representation of the target model as “augmented reality”, an automated comparison between the target model of the formwork and at least one image and/or scan recorded by a camera of the mobile device can also be performed. This comparison can be used to check whether at least one structural element and/or accessory part of the formwork has been correctly installed on the construction site.

It is optional whether the comparison is made in the internal coordinate system of the mobile device or in the absolute coordinate system of the construction site. If the comparison is carried out in the internal coordinate system of the mobile device, for example, a perspective-correct two-dimensional projection of the three-dimensional model can be created and compared with the image and/or scan captured by the camera of the mobile device. However, it is also possible, for example, merely to check whether the image, or scan, is consistent with the hypothesis that the component and/or accessory has been correctly installed.

In particular, the geometric feature used to generate one or more equations may be, for example, a two- or three-dimensional marking code applied to the construction site. The positions of such marking codes can be accurately measured or determined in the absolute coordinate system of the construction site.

In a further advantageous embodiment, at least one building element and/or accessory is selected as a geometric feature. For example, the positions of clearly identifiable pipes or other plant components can be taken from a building model of an industrial plant.

In another particularly advantageous embodiment, detecting the geometric feature includes determining, from the distortion of the geometric feature in the image and/or scan, a spatial direction of the mobile device to the geometric feature at the time of capture. Alternatively, or in combination, determining from the size of the geometric feature in the image and/or scan a distance of the mobile device to the geometric feature at the time of capture.

In this way, the information about which geometric features are located at which known positions can be optimally exploited. In particular, for example, one and the same geometric feature, whose position and orientation have been measured once in the absolute coordinate system of the construction site, can be used several times for calibration by taking images and/or scans from several distances and perspectives.

Furthermore, information about multiple geometric features detectable in the same image and/or scan can also be extracted from the same image and/or scan. This information is then linked to the same sensor-determined position of the mobile device in the internal coordinate system of the mobile device.

In a further particularly advantageous embodiment, the equations in the system of equations are assigned different weights depending on the reliability of the information they contain. In this way, account can be taken of the fact that not all of the many possible sources of information can provide the same accuracy. Information with a lower reliability does not necessarily have to be discarded, but can also contribute to the calibration, while at the same time ensuring that particularly precise information is not diluted.

In another particularly advantageous embodiment, the system of equations is solved iteratively starting from initial values obtained from a priori information about the site. In this way, the solution converges faster, and the probability of being “stuck” at a side optimum is reduced.

In another particularly advantageous embodiment, recognizing the geometric feature includes recognizing at least one surface, and/or at least one point, in the image and/or scan and associating it with at least one surface, and/or at least one point, of the geometric feature.

Mature solutions are already available for the recognition of surfaces as such, so that effort only needs to be invested in the assignment to the surface of the geometric feature. For example, the assignment can be requested by the operator of the mobile device.

For example, salient points of geometric features can be used as points, such as vertices or intersections of multiple geometric features.

In a further particularly advantageous embodiment, at least one geometric feature is selected whose position in the absolute coordinate system of the construction site is derived from a predetermined three-dimensional nominal model of the construction site, and/or of a structure to be erected or modified. Then, the calibration can be automated to an even higher degree, since no manual measurement of the position and orientation of the geometric feature is required. In particular, many more geometric features can be analyzed and correspondingly more equations can be established to increase the accuracy of the calibration finally obtained.

For example, at least one assignment of a geometric feature depicted in the image and/or scan to a geometric feature contained in the three-dimensional nominal model of the construction site may be requested by an operator. If automatic mapping is not possible beyond doubt, then such operator contribution is a useful addition. Humans tend to have good abilities to make such mappings, and unlike manually measuring the position and orientation of a geometric feature, there is no degradation of accuracy to worry about here.

As previously explained, geometric features can be recognized not only in images and/or scans, but alternatively or in combination thereto also in a three-dimensional actual model of the construction site determined from multiple images and/or scans. By aggregating the information from multiple images and/or scans in such a three-dimensional actual model, the influence of inaccuracies that arise when capturing individual images and/or scans due to the limited pixel resolution of the camera used, among other things, can be pushed back.

In a further particularly advantageous embodiment, generating a three-dimensional actual model of the construction site from a plurality of images and/or scans includes identifying three-dimensional patterns and shapes, and/or two-dimensional projections thereof, in the images and/or scans. For example, from the distortion and size of the pattern, or shape, the distance to the location where the shape, or pattern, is located and the perspective under which the shape, or pattern, is visible in the image and/or scan can be determined. With this information, the pattern or shape can be correctly placed in the three-dimensional actual model.

Alternatively, or in combination, the pixels of the images and/or scans can be aggregated to form a point cloud in three-dimensional space, for example using the methods of photogrammetry. The three-dimensional patterns or shapes can then be detected in this point cloud.

For example, a live data stream of the camera image of the mobile device may be streamed to an external server where the live camera image is split into individual pixels. Patterns and shapes, or two-dimensional projections thereof, may then be detected from the composition of the individual pixels, for example using machine learning. The analysis of the composition may relate, for example, to the distances between the pixels, the colour information of the individual pixels, and/or the clustering or grouping of pixels of similar colour information and the shape of that grouping. Continuous analysis of the data transmitted with the live transmission may then lead to the three-dimensional actual model of the environment of the mobile device, which is composed of points in three-dimensional space forming a point cloud. This actual model can then be compared, for example in terms of the extracted color information and patterns, to a three-dimensional building model.

Here, color information and extracted patterns form two information layers on the basis of which the comparison can be carried out, whereby the main part of the information is in the extracted patterns, i.e. in the shape information. The color information can be used to pre-filter which elements of the building model are included in the comparison of the shape information. If, possibly after scaling, rotating, shifting or other operations, at least a predetermined percentage of the points of the point cloud match parts of the three-dimensional building model, then this means that the geometric features in the three-dimensional building model have been detected in the three-dimensional actual model. From the positions and orientations of the mobile device detected by sensors during image acquisition, in conjunction with the operations that were necessary to bring the actual model into the predetermined degree of correspondence with the three-dimensional building model, one or more equations for the sought transformation between the internal coordinate system of the mobile device and the absolute coordinate system of the building site are obtained.

The higher the degree of agreement between the three-dimensional actual model and the three-dimensional building model, the more the solution space of the equations following from the comparison is restricted. A very good match between the three-dimensional point cloud extracted from the stream of two-dimensional images and the three-dimensional building model can unambiguously, or almost unambiguously, define the sought transformation between the internal coordinate system and the absolute coordinate system. On the other hand, if the agreement is less good, the equations following from the comparison of the point cloud with the building model may be further supplemented with other equations. For example, equations obtained from the comparison of a position in the absolute coordinate system of the building site determined with a positioning system with a position in the internal coordinate system of the mobile device determined by sensors can be used. Direct recognition of geometric features in the two-dimensional images can also be used to obtain further equations.

In another particularly advantageous embodiment, image pixels whose color information is similar are considered to belong to the same three-dimensional pattern, or to the same three-dimensional shape, and/or to the same point in three-dimensional space. Behind this is the realization that especially many objects on construction sites (such as building elements or accessories) have comparatively few colored features.

Accordingly, in a further advantageous embodiment, geometric features detected in the three-dimensional actual model may also be preselected based on the color information of the pixels in images.

According to what has been described above, the invention also relates to a method for computer-assisted quality control of a predetermined formwork, and/or a predetermined scaffold, on a construction site. Here, an internal coordinate system of a mobile device is first calibrated to an absolute coordinate system of the construction site using the previously described method.

Based on this calibration, a three-dimensional target model of the formwork or scaffolding created in the absolute coordinate system of the construction site and/or at least one spatially resolved state variable of the formwork or scaffolding recorded in the absolute coordinate system of the construction site can be transformed into the internal coordinate system of the mobile device. The target model, and/or the state variable, of the formwork, or scaffolding, may then be overlaid with a current view of the construction site from the perspective of the mobile device. As previously described, this overlay may be made from a camera image captured by the mobile device and displayed on a display of the mobile device. However, the overlay may also be partially transparent to a direct optical view to the physical scene, for example. This makes it possible to visually check whether the actual physical structure of the formwork or scaffolding corresponds to the three-dimensional target model.

Alternatively, or in combination therewith, a comparison between the target model of the formwork or scaffolding, on the one hand, and at least one image and/or scan recorded by the mobile device, and/or at least one actual model of the construction site determined from a plurality of such images and/or scans, on the other hand, can be used to check whether at least one structural element and/or accessory part of the formwork or scaffolding has been correctly installed at the construction site. This check can be fully automatic and does not even require an image output to the user of the mobile device.

In particular, the condition variable can be a variable that is important with regard to the quality and/or safety of the formwork or scaffolding, but which cannot be detected by a human being without technical aids in the physical world. An example of this is a mechanical load to which the formwork, the scaffolding or a part thereof is subjected.

For example, a formwork filled with concrete is loaded with a pressure from the inside due to the gravity pressure of the concrete. Scaffolding parts can, for example, be loaded with a compressive force, with a tensile force and/or with a torque.

For example, the condition variable may comprise output data from at least one sensor configured to directly or indirectly measure the condition variable at one or more locations on the formwork, or scaffold. For example, strain gauges or other load sensors may be attached to the formwork, or scaffolding. However, the state variable can also be calculated on an external server, for example. For example, given the internal geometry of the formwork and the amount of concrete poured, the gravity pressure acting on each point of the formwork is known.

By visualizing a mechanical load, it is possible, for example, to detect assembly errors that cause the formwork or scaffolding to be loaded unevenly and/or overloaded in certain areas. For example, a missing component at one point can result in components at another point having to compensate for this missing component and being loaded more heavily accordingly. This can lead to a sudden failure of components with a corresponding risk of accident.

A component does not even have to be completely missing to cause such consequences. An incorrect assembly of the component can already be sufficient. If, for example, four supports on which a scaffold stands are of uneven length or incorrectly adjusted to the unevenness of the ground, this can result in the weight of the scaffold being borne by only three instead of four supports. Visually, it is impossible to tell that the fourth prop is only resting loosely on the ground and is not transmitting any force to the ground.

The method may be carried out, at least in part, by one or more computers or mobile devices, and thus may in particular be implemented in software. Therefore, the invention also relates to a computer program comprising machine-readable instructions which, when executed on at least one computer, and/or on at least one mobile device, cause the computer, and/or the mobile device, to perform one of the described methods. Likewise, the invention also relates to a machine-readable data carrier, and/or to a download product, comprising the computer program.

### SPECIAL DESCRIPTION PART

Hereinafter, the subject matter of the invention will be explained with reference to figures without limiting the subject matter of the invention herein. It is shown:

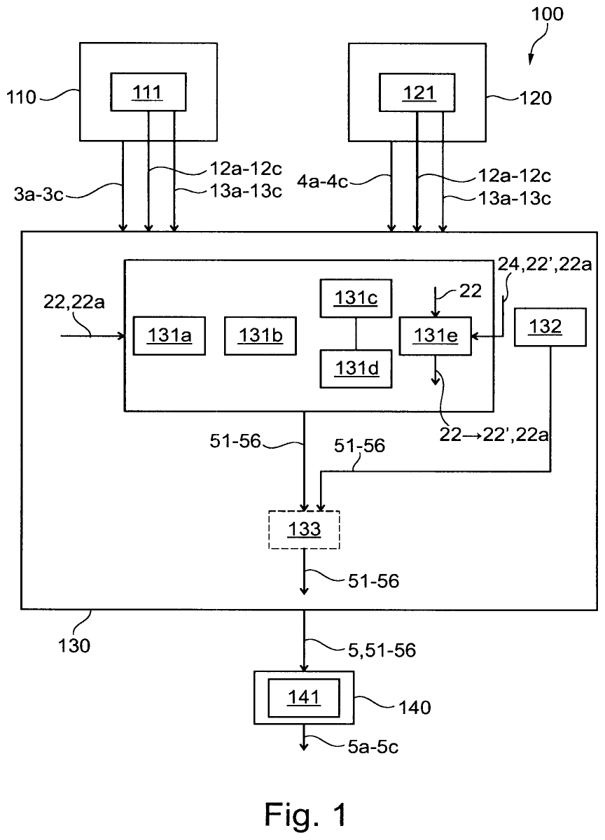

FIG. 1: Flow chart of an embodiment of method 100;

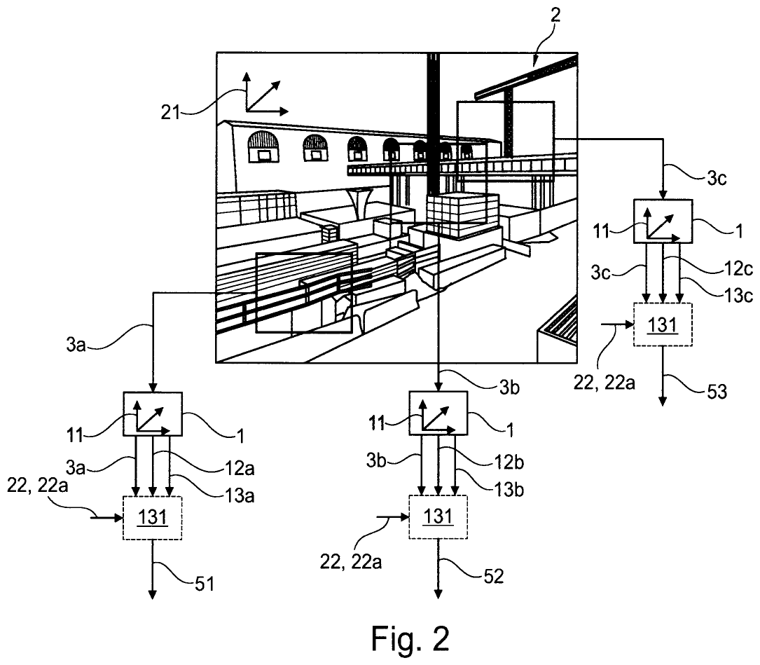

FIG. 2: Example of obtaining equations 51-53 by recognizing 131 geometric features 22;

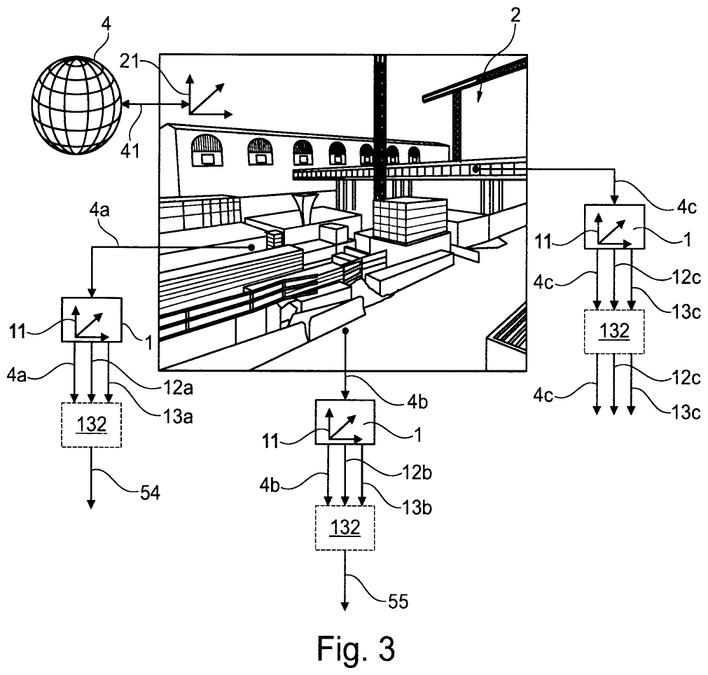

FIG. 3: Exemplary obtaining of equations 54-56 by matching positions 4a-4c determined by a positioning system with positions 12a-12c and/or orientations 13a-13c determined by sensors;

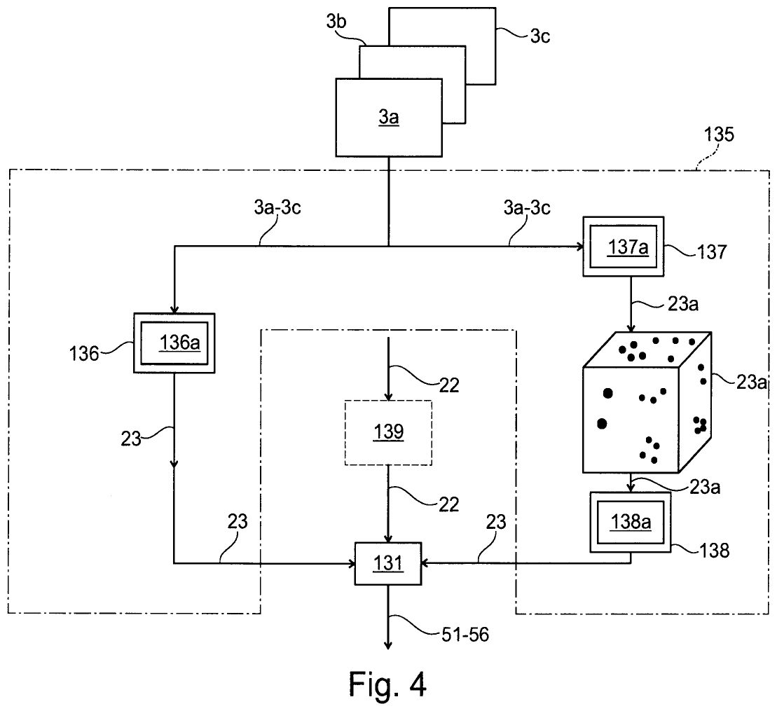

FIG. 4: Exemplary extraction of equations 51-56 with the help of a three-dimensional actual model 23 of the construction site 2;

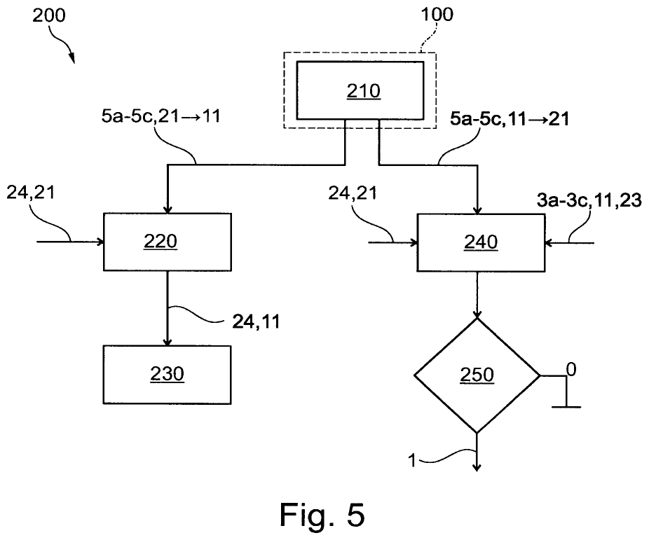

FIG. 5: Flow chart of an embodiment of method 200.

FIG. 1 is an exemplary flowchart of an embodiment of the method 100. In step 110, at least one image and/or scan 3a-3c showing at least a portion of the construction site 2 is captured at each of a plurality of positions on the construction site 2, and/or with a plurality of orientations of the mobile device 1. Thus, the user of the mobile device 1 may, for example, walk around the construction site 2 with the mobile device, or may stand at a fixed position and rotate around its own axis. In addition, for each recording 110 according to block 111, the position 12a-12c and/or orientation 13a-13c of the mobile device 1 in the internal coordinate system 11 of the mobile device 1 is also sensed. Data acquisition in this manner is detailed in FIG. 2.

Alternatively, or also in combination therewith, in step 120 at the plurality of positions, or with the plurality of orientations of the mobile device 1, the position 4a-4c of the mobile device 1 can be determined in each case with a positioning system in a coordinate system 4 which is in a known fixed relation 41 to the absolute coordinate system 21 of the construction site 2. Thereby, analogously to block 111, according to block 121 also the position 12a-12c and/or orientation 13a-13c of the mobile device 1 in the internal coordinate system 11 of the mobile device 1 is sensed. The data acquisition in this way is described in more detail in FIG. 3.

In step 130, equations 51-56 are established in unknowns 5a-5c characterizing the transformation sought between the internal coordinate system 11 of the mobile device 1 and the absolute coordinate system 21 of the site 2. This can be done, individually or in combination, in two ways.

According to block 131, at least one geometric feature 22 having a known position 22a in the absolute coordinate system 21 of the construction site 2 is detected in an image and/or scan 3a-3c, and/or in a three-dimensional actual model 23 of the construction site 2 determined from a plurality of such images and/or scans.

According to block 132, the position 4a-4c determined with the positioning system is related to the position 12a-12c and/or orientation 13a-13c determined sensorially in the internal coordinate system 11 of the mobile device 1.

There are again several exemplary options for detecting 131 geometric features 22, which are shown in more detail within the box 131 and may be used individually or in combination.

According to block 131a, a spatial direction of the mobile device 1 with respect to the geometric feature 22 at the time the image was captured can be determined from the distortion of the geometric feature 22 in the image and/or scan 3a-3c. That is, the distortion provides an indication of the perspective from which the geometric feature 22 was captured, and this perspective in turn indicates the spatial direction.

According to block 131b, a distance of the mobile device 1 to the geometric feature 22 at the time of acquisition may be determined from the size of the geometric feature 22 in the image and/or scan 3a-3c.

According to block 131c, at least one surface, and/or at least one point, may be detected in order to subsequently associate this surface, or point, with a corresponding surface, or point, of geometric feature 22 in block 131d.

According to block 131e, at least one mapping of a geometric feature 22 imaged in the image and/or scan 3a-3c to a geometric feature 22′ contained in a three-dimensional nominal model 24 of the site 2 may be requested by an operator. In this way, the known position 22a of the geometric feature 22′ stored in the nominal model 24 may be associated with the imaged geometric feature 22a.

Optionally, equations 51-56 may be weighted differently according to block 133 depending on the reliability of the information contained in each.

The equations 51-56, obtained by whatever means, form a system of equations 5 in the unknowns 5a-5c. In step 140, this system of equations 5 is solved according to the unknowns 5a-5c, optionally following an iterative path according to block 141 starting from initial values obtained from a priori information about the site 2. The values of the unknowns 5a-5c obtained as solutions characterize the transformation sought between the internal coordinate system 11 of the mobile device 1 and the absolute coordinate system 21 of the site 2.

FIG. 2 shows an example of obtaining equations 51-53 from two-dimensional images 3a-3c showing different portions of the same site 2. In this example, as in FIG. 3, it is simply assumed that the mobile device 1 can capture two-dimensional images 3a-3c. This capability is common to the vast majority of mobile devices out of the box, whereas capturing three-dimensional images or scans requires advanced hardware or additional programs (apps).

The images 3a-3c each live in the internal coordinate system 11 of the mobile device 1, and during image acquisition the respective position 12a-12c, and/or the respective orientation 13a-13c, of the mobile device 1 are detected by sensors. In the images 3a-3c, according to block 131, geometric features 22 with known position 22a in the absolute coordinate system 21 of the construction site 2 are respectively detected. This known position 22a is consistent with the fact that the geometric feature 22 has been detected in images 3a-3c, in conjunction with the respective position 12a-12c and/or orientation 13a-13c of the mobile device 1, only for certain transformations between the internal coordinate system 11 of the mobile device 1 and the absolute coordinate system 21 of the construction site 2. For example, the detection of a crane in an upright position is not coherent with a transformation in which it should actually be upside down. On the other hand, for a single detection of a feature 22 in an image 3a-3c, there are usually multiple transformations coherent with that detection. By combining multiple equations 51-53 into one system of equations 5, such ambiguities are resolved, and the influence of errors in physical detection is pushed back.

FIG. 3 illustrates clearly the obtaining of equations 54-56 by means of the comparison 132 between, on the one hand, positions 4a-4c of the mobile device 1 determined by a positioning system and, on the other hand, positions 12a-12c, and/or orientations 13a-13c, determined by sensors. In this example, the positions 4a-4c live in a world coordinate system 4 which has a known fixed relation 41 to the absolute coordinate system 21 of the site 2. In the example drawn in FIG. 3, the absolute coordinate system 21 of the site 2 is a Cartesian coordinate system “suspended” from a fixed point in world coordinates characterized by longitude and latitude. Any comparison of the positions in the different coordinate systems 4 and 11 yields at least one equation 54-56, where the world coordinates 4 can be expressed in coordinates of the absolute coordinate system 21 of the construction site 2 by the known relation 41.

FIG. 4 illustrates various ways in which a three-dimensional actual model 23 of the construction site 2 can be obtained from a plurality of images and/or scans 3a-3c according to block 135.

According to block 136, three-dimensional patterns and shapes, and/or two-dimensional projections thereof, may be recognized in the images and/or scans 3a-3c. Then, the pattern, or shape, may be directly inserted into a three-dimensional actual model 23 of the construction site 2. This actual model relates to what is seen on the construction site 2, but lives in the internal coordinate system 11 of the mobile device 1 in which the underlying images and/or scans 3a-3c live.

According to block 137, the pixels of the images and/or scans 3a-3c may be aggregated to form a point cloud 23a in three-dimensional space, again still in the internal coordinate system 11 of the mobile device 1. The three-dimensional actual model 23 of the construction site 2 may then be generated according to block 138 by detecting three-dimensional patterns or shapes in this point cloud 23a. That is, the point cloud provides clues as to which patterns or shapes are to be used where in three-dimensional space, and the patterns or shapes then collectively form the three-dimensional actual model 23 of the job site 2, still in the internal coordinate system 11.

The comparison with the absolute coordinate system 21 of the site 2 does not take place until block 131, when geometric features 22 with known positions 22a in the absolute coordinate system 21 of the site 2 are detected in the three-dimensional actual model 23. Equations 51-56 are obtained from this.

Optionally, for this comparison according to block 139, those geometric features 22 that can be seen in the actual model 23 can be preselected based on the color information of pixels in images 3a-3c.

Optionally, according to blocks 136a, 137a, and 138a, respectively, pixels whose color information is similar may be judged to belong to the same pattern, shape, or point in three-dimensional space, respectively.

FIG. 5 shows an example of the computer-aided quality control method 200. In step 210, the internal coordinate system 11 of the mobile device 1 is calibrated to the absolute coordinate system 21 of the construction site 2 using the previously described method 100. The solutions 5a-5c of the system of equations 5 obtained in this process characterize both a transformation from the internal coordinate system 11 to the absolute coordinate system 21 and a reverse transformation from the absolute coordinate system 21 to the internal coordinate system 11.

In step 220, a three-dimensional target model 24 created in the absolute coordinate system 21 of the construction site 2 can thus be transformed into the internal coordinate system 11 of the mobile device 1. In this internal coordinate system 11, the target model 24 can then be superimposed in step 230 on a current view of the construction site 2 from the perspective of the mobile device 1.

In step 240, the images and/or scans 3a-3c, and/or a three-dimensional actual model 23 of the construction site 2 created therefrom, can be transformed from the internal coordinate system 11 into the absolute coordinate system 21 and compared there with the nominal model 24 of the formwork, or of the scaffolding. On the basis of this comparison, it can be checked in step 250 whether at least one construction element and/or accessory of the formwork, or of the scaffolding, has been correctly installed at the construction site 2.

### LIST OF REFERENCE SIGNS

1 mobile device

11 internal coordinate system of the mobile device 1

12a-12c positions of the mobile device 1

13a-13c orientations of the mobile device 1

2 construction site

21 absolute coordinate system of the construction site 2

22, 22′ geometric characteristic

22a position of geometric feature 22

23 three-dimensional actual model of the construction site 2

24 three-dimensional nominal model of scaffolding and/or formwork

3a-3c images or scans

4 coordinate system of the positioning system

41 relation between coordinate systems 4 and 21

4a-4c positions determined in coordinate system 4

5 equation system

5a-5c unknowns of the system of equations 5

51-56 equations, form system of equations 5

100 procedure for calibrating coordinate systems 11 and 21

110 capturing images and/or scans 3a-3c

111 sensory detection of positions 12a-12c, orientations 13a-13c

120 determining positions 4a-4c with positioning system

121 sensory detection of positions 12a-12c, orientations 13a-13c

130 forming equations 51-56

131 recognizing geometric features 22 with known positions 22a

131a detecting perspective from distortions in the image/scan 3a-3c

131b detecting distances from size in image/scan 3a-3c

131c recognition of surfaces and/or points

131d assigning surfaces and/or points

131e requesting an assignment from an operator

132 comparing positions 4a-4c with sensor measurement 12a-12c, 13a-13c

133 weighing equations 51-57

135 creating a three-dimensional actual model 23

136 recognizing the projections of shapes and patterns

136a consideration of colour information

137 aggregating the images/scans 3a-3c into a point cloud 23a

137a consideration of colour information

138 detecting shapes and patterns in the point cloud 23a

138a consideration of colour information

139 pre-selection of geometric features 22 by color information

140 solving the system of equations 5 according to the unknowns 5a-5c

141 iterative approach to solving 140

200 procedures for quality control

210 calibrating the coordinate systems 11, 21 with method 100

220 transforming the nominal model 24 into the coordinate system 11

230 overlaying the nominal model 24 with the current view of the construction site 2

240 comparing the target model with images/scans 3a-3c, actual model 23

250 check for correct installation of component/accessory part

1. A method (100) for calibrating an internal coordinate system (11) of a mobile device (1) against an absolute coordinate system (21) of a construction site (2), comprising the steps:
at a plurality of positions on the construction site (2), and/or with a plurality of orientations of the mobile device (1), in each case at least one image and/or scan (3a-3c) showing at least a part of the construction site (2) is recorded (110) with the mobile device (1), and/or the position (4a-4c) of the mobile device (1) in a coordinate system (4) which is in a known fixed relation (41) to the absolute coordinate system (21) of the construction site (2) is determined (120) using a terrestrial or satellite-based positioning system;
for each recording (110) and/or position determination (120), the position (12a-12c) and/or orientation (13a-13c) of the mobile device (1) in the internal coordinate system (11) of the mobile device (1) is additionally sensed (111, 121);
equations (51-56) are established (130) with unknowns (5a-5c) characterizing the sought transformation between the internal coordinate system (11) of the mobile equipment (1) and the absolute coordinate system (21) of the site (2), these equations (51-56) being obtained by
detecting (131) at least one geometric feature (22) with a known position (22a) in the absolute coordinate system (21) of the construction site (2) in an image and/or scan (3a-3c), and/or in a three-dimensional actual-model (23) of the construction site (2) determined from a plurality of images and/or scans (3a-3c), and/or
relating (132) the position (4a-4c) determined with the positioning system to the position (12a-12c) and/or orientation (13a-13c) sensed in the internal coordinate system (11) of the mobile device (1);
determining (140) the unknowns (5a-5c) as solutions of a system of equations (5) formed from the established equations (51-56).

2. The method (100) according to claim 1, wherein at least one two- or three-dimensional marking code applied to the construction site (2) is chosen as geometric feature (22).

3. The method (100) according to claim 1, wherein at least one construction element and/or accessory is chosen as geometric feature (22).

4. wherein detecting (131) the geometric feature (22) includes,
determining (131a), from the distortion of the geometric feature (22) in the image and/or scan (3a-3c), a spatial direction of the mobile device (1) to the geometric feature (22) at the time of recording, and/or
determining (131b), from the size of the geometric feature (22) in the image and/or scan (3a-3c), a distance of the mobile device (1) to the geometric feature (22) at the time of recording.

5. The method (100) according to claim 1, wherein different weights are assigned (133) to the equations (51-56) in the system of equations (5) depending on the reliability of the information contained therein.

6. The method (100) according to claim 1, wherein the system of equations (5) is solved iteratively (141) starting from initial values obtained from a priori information about the site (2).

7. The method (100) according to claim 1, wherein the recognizing (131) of the geometric feature (22) comprises recognizing (131c) at least one surface, and/or at least one point, in the image or scan (3a-3c) and associating (131d) this to at least one surface, or at least one point, respectively, of the geometric feature (22).

8. The method (100) according to claim 1, wherein at least one geometric feature (22) is selected whose position (22a) in the absolute coordinate system (21) of the construction site (2) arises from a predetermined three-dimensional nominal-model (24) of the construction site (2), and/or of a structure to be erected or modified.

9. The method (100) according to claim 8, wherein at least one assignment of a geometric feature (22) depicted in the image or scan (3a-3c) to a geometric feature (22′) contained in the three-dimensional nominal-model (24) of the construction site (2) is requested (131e) from an operator.

10. The method (100) according to claim 1, wherein generating (135) a three-dimensional actual-model (23) of the construction site (2) from a plurality of images and/or scans (3a-3c) includes detecting (136) three-dimensional patterns and shapes, and/or two-dimensional projections thereof, in the images and/or scans (3a-3c), and/or aggregating (137) the pixels of the images and/or scans (3a-3c) into a point cloud (23a) in three-dimensional space, and recognizing (138) the three-dimensional patterns and/or shapes in this point cloud (23a).

11. The method (100) according to claim 10, wherein image pixels whose color information is similar are evaluated (136a, 137a, 138a) as belonging to the same three-dimensional pattern, or to the same three-dimensional shape, and/or to the same point in three-dimensional space.

12. The method (100) according to claim 1, wherein geometric features (22) detected (131) in the three-dimensional actual-model (23) are preselected (139) based on the color information of the pixels in images (3a-3c).

13. A method (200) for computer-aided quality control of a predetermined formwork, and/or a predetermined scaffold, at a construction site (2) comprising the steps:
an internal coordinate system (11) of a mobile device (1) is calibrated (210) to an absolute coordinate system (21) of the site (2) by the method (100) according to claim 1;
a three-dimensional nominal-model (24) of the formwork or of the scaffolding created in the absolute coordinate system (21) of the construction site (2), and/or at least one spatially resolved state variable of the formwork or of the scaffolding recorded in the absolute coordinate system (21) of the construction site (2), is transformed (220) into the internal coordinate system (11) of the mobile device (1), and the nominal-model (24), and/or the state variable of the formwork or scaffolding, is superimposed (230) on a current view of the construction site (2) from the perspective of the mobile device (1), and/or
on the basis of a comparison (240) between the nominal-model (24) of the formwork or of the scaffolding, on the one hand, and at least one image and/or scan (3a-3c) recorded by the mobile device (1) and/or at least one actual-model (23) of the construction site (2) determined from a plurality of such images and/or scans (3a-3c), on the other hand, it is checked (250) whether at least one structural element and/or accessory of the formwork or of the scaffolding has been correctly installed on the construction site (2).

14. A computer program comprising machine-readable instructions which, when executed on at least one computer, and/or on at least one mobile device, cause the computer, and/or the mobile device, to perform a method (100, 200) according to claim 1.

15. A machine-readable data carrier and/or download product comprising the computer program according to claim 14.
